(19) United States
(12) Patent Application Publication
(10) Pub. No.: US 2022/0238830 A1
(43) Pub. Date: Jul. 28, 2022

(54) LIGHT-EMITTING ELEMENT AND LIGHT-EMITTING DEVICE

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/614,938

(22) PCT Filed: Jun. 4, 2019
(86) PCT No.: PCT/JP2019/022211

§ 371 Date: Nov. 29, 2021

(51) Int. Cl. H01L 51/50; H01L 51/52

(52) U.S. Cl. CPC H01L 51/5004; H01L 51/502; H01L 2251/558; H01L 51/5072; H01L 2251/552; H01L 51/5221

(57) ABSTRACT

A light-emitting element includes: an anode; a cathode; a quantum-dot layer provided between the anode and the cathode, and containing quantum dots; and an electron-transport layer provided between the cathode and the quantum-dot layer, and placed in contact with the quantum-dot layer. In an interface between the quantum-dot layer and the electron-transport layer, the quantum-dot layer is greater in ionization potential than the electron-transport layer, and the quantum-dot layer is greater in bandgap than the electron-transport layer.

### TECHNICAL FIELD

The disclosure relates to a light-emitting element containing quantum dots, and a light-emitting device including the light-emitting element.

### BACKGROUND ART

Patent Document 1 discloses a light-emitting device containing semiconductor nanocrystals.

### CITATION LIST

### Patent Literature

[Patent Document 1] Japanese Unexamined Patent Application Publication No. 2012-023388

### SUMMARY

### Technical Problem

As to a known light-emitting element containing quantum dots, carrier concentration tends to be low in an electron-transport layer between a cathode and a quantum-dot layer. Accordingly, efficiency in electron transport from the cathode to the quantum-dot layer tends to be low.

### Solution to Problem

In order to solve the above problem, the light-emitting element of the disclosure includes: an anode; a cathode; a quantum-dot layer provided between the anode and the cathode, and containing quantum dots; and an electron-transport layer provided between the cathode and the quantum-dot layer, and placed in contact with the quantum-dot layer. In an interface between the quantum-dot layer and the electron-transport layer, the quantum-dot layer is greater in ionization potential than the electron-transport layer, and the quantum-dot layer is greater in bandgap than the electron-transport layer.

### Advantageous Effect of Disclosure

The disclosure can provide a light-emitting element that achieves higher efficiency in electron transport from a cathode to a quantum-dot layer.

### BRIEF DESCRIPTION OF DRAWINGS

FIG. 1 is a schematic cross-sectional view of a light-emitting device according to a first embodiment, and an energy band diagram of layers in a light-emitting element of the light-emitting device.

FIG. 2 is an energy band diagram illustrating an example of variation in a LUMO level and a Fermi level of each of an electron-transport layer and a cathode before and after junction.

FIG. 3 is an energy band diagram illustrating an example of variation in a LUMO level of each of a quantum-dot layer and the electron-transport layer before and after application of voltage.

FIG. 4 is a schematic cross-sectional view of the light-emitting device according to a second embodiment, and an energy band diagram of layers in the light-emitting element of the light-emitting device.

FIG. 5 is an energy band diagram of the quantum-dot layer and the electron-transport layer, illustrating advantageous effects of the light-emitting device according to the second embodiment.

FIG. 6 is a graph showing actually measured values of voltage-current density characteristics of the light-emitting element according to the second embodiment, and a result of curve-fitting of the actually measured values.

FIG. 7 illustrates graphs showing parameters to be used for measuring performance of the light-emitting elements according to the embodiments.

### DESCRIPTION OF EMBODIMENTS

### First Embodiment

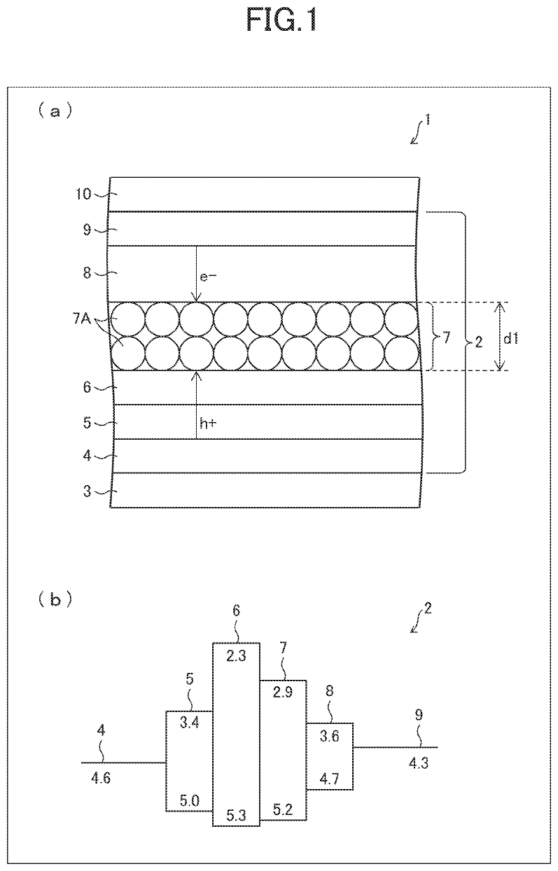

FIG. 1(a) is a schematic cross-sectional view of a light-emitting device 1 according to this embodiment. FIG. 1(a) shows that the light-emitting device 1 according to this embodiment includes: a light-emitting element 2; and an array substrate 3. The light-emitting device 1 is structured to include the array substrate 3 formed of not-shown thin-film transistors (TFTs), and the light-emitting element 2 multilayered and stacked on the array substrate 3. Note that, in DESCRIPTION, a direction from the light-emitting element 2 toward the array substrate 3 in the light-emitting device 1 is referred to as a “downward direction”, and a direction from the array substrate 3 toward the light-emitting element 2 in the light-emitting device 1 is referred to as an “upward direction”.

FIG. 1(b) is an energy band diagram of the layers in the light-emitting element 2. In FIG. 1(b), any energy bands of the layers are represented with reference to a vacuum level.

The light-emitting element 2 includes: a first electrode 4; a hole-injection layer 5; a hole-transport layer 6; a quantum-dot layer 7; an electron-transport layer 8; a second electrode 9; and a barrier layer 10, all of which are stacked on top of another in the stated order from below. The first electrode 4, which is included in the light-emitting element 2 formed above the array substrate 3, is electrically connected to the TFTs of the array substrate 3.

Here, in FIG. 1(b), the first electrode 4 and the second electrode 9 are assigned their respective work functions. In FIG. 1(b), the layers from the hole-injection layer 5 to the electron-transport layer 8 are assigned their respective ionization potentials and electron affinities. The numeric values in FIG. 1(b) denote the work functions, the ionization potentials, and the electron affinities of the layers expressed in the unit eV.

Note that the work function of each of the electrodes corresponds to a difference between the Fermi level and the vacuum level of the electrode. Moreover, if the semiconductor layers are made of an organic compound, the ionization potential of each of the semiconductor layers corresponds to a difference between the HOMO level and the vacuum level of the semiconductor layer. If the semiconductor layers are made of an inorganic compound, the ionization potential of each of the semiconductor layers corresponds to a difference between the top of the valence band and the vacuum level of the semiconductor layer. Likewise, if the semiconductor layers are made of an organic compound, the electron affinity of each of the semiconductor layers corresponds to a difference between the LUMO level and the vacuum level of the semiconductor layer. If the semiconductor layers are made of an inorganic compound, the electron affinity of each of the semiconductor layers corresponds to a difference between the bottom of the conduction band and the vacuum level of the semiconductor layer.

The first electrode 4 and the second electrode 9, containing a conductive material, are respectively and electrically connected to the hole-injection layer 5 and the electron-transport layer 8. In this embodiment, the first electrode 4 is an anode, and the second electrode 9 is a cathode.

Either the first electrode 4 or the second electrode 9 is a transparent electrode. The transparent electrode may be made of, for example, ITO, IZO, ZnO, AZO, BZO, or FTO, and deposited by, for example, sputtering. Moreover, either the first electrode 4 or the second electrode 9 may contain a metal material. The metal material preferably contain: one of such materials as Al, Cu, Au, Ag, or Mg that is high in reflectance of visible light; or an alloy of the materials.

In this embodiment, the first electrode 4 is made of ITO, and the second electrode 9 is made of Al. In this case, the first electrode 4 has a work function of 4.6 eV, and the second electrode 9 has a work function of 4.3 eV. In this embodiment, the first electrode 4 is formed by sputtering, and the second electrode 9 is formed by vacuum vapor deposition.

The hole-injection layer 5 can be made of a known material used for such elements as light-emitting elements containing quantum dots and organic EL elements. An example of a commonly known material of the hole-injection layer 5 includes PEDOT-PSS, an organic compound.

Similar to the hole-injection layer 5, the hole-transport layer 6 can be made of a known material used for such elements as light-emitting elements containing quantum dots and organic EL elements. Examples of the material of the hole-transport layer 6 include conductive organic compounds such as TFB and PVK, or metal oxides such as NiO, Cr₂O₃, MgO, MgZnO, LaNiO₃, MoO₃, and WO₃.

Other than the above materials, materials used for such elements as light-emitting elements commonly containing quantum dots and organic EL elements can be used without problem for the hole-injection layer 5 or the hole-transport layer 6. In particular, materials of the hole-injection layer 5 and the hole-transport layer 6 are preferably great in electron affinity and ionization potential.

The hole-injection layer 5 and the hole-transport layer 6 can be formed by a commonly used technique such as vacuum vapor deposition, sputtering, or application of a colloidal solution made of a solvent into which nano particles of those materials are dispersed.

In this embodiment, the hole-injection layer 5 is made of PEDOT-PSS, and the hole-transport layer 6 is made of TFB. In this case, the hole-injection layer 5 has an ionization potential of 5.0 eV and an electron affinity of 3.4 eV. Likewise, the hole-transport layer 6 has an ionization potential of 5.3 eV and an electron affinity of 2.3 eV.

The quantum-dot layer 7 includes quantum dots (semiconductor nano particles) 7A multilayered. The quantum-dot layer 7 may have a film thickness d1 of, for example, 30 nm.

Each of the quantum dots 7A includes a core and a shell coating the core. Each quantum dot 7A has the shell surface combined with a ligand made of an organic compound, making it possible to deactivate, for example, dangling bonds or defects possibly acting as a center of non-light-emitting recombination on the shell surface. Moreover, the ligand can encourage the quantum dots 7A to further disperse in the solvent of the colloidal solution.

The quantum dots 7A, having a valence band and a conduction band, are a light-emitting material emitting light by recombination of holes occupying the top of the valence band and electrons occupying the bottom of the conduction band. Because of a three-dimensional quantum confinement effect, the light emitted from the quantum dots 7A has a narrow spectrum, and thus can be relatively deep in chromaticity.

An example of the quantum dots 7A may include semi-Cd-based conductive nano particles formed in a core/shell structure. Each of the Quantum dots 7A may have a core made of CdSe and a shell made of ZnS. Alternatively, the quantum dots 7A may be formed in a core/shell structure of, for example, CdSe/CdS, InP/ZnS, ZnSe/ZnS, or CIGS/ZnS. Furthermore, the quantum dots 7A may contain Si, C, or a nitride-based compound.

The quantum dots 7A have a particle size ranging approximately from 2 to 15 nm. The wavelength of light emitted from the quantum dots 7A can be controlled with the particle size of the quantum dots 7A. Hence, through the control of the particle size of the quantum dots 7A, the wavelength can be controlled of the light to be emitted from the light-emitting device 1.

Here, if the particle size of the quantum dots 7A is distributed, the distribution of the particle size is a factor to determine a half width of the wavelength of the emitted light. Hence, if each of the quantum dots 7A has a different particle size, the half width of the wavelength of the light emitted from the quantum-dot layer 7 ranges widely. Thus, in order to ensure color gamut and color reproduction of a display, the particle size distribution of the quantum dots 7A in this embodiment may preferably be controlled within a narrow range.

In forming the quantum-dot layer 7, the quantum dots 7A are dispersed in an organic solvent such as hexane or toluene so that a colloidal solution is prepared. The colloidal solution is applied by spin coating or ink-jet printing so that the quantum-dot layer 7 is formed. Mixed with the fluid disperse of the quantum dots 7A may be a material in which such a substance as thiol or amine is dispersed.

In this embodiment, the colloidal solution contains the quantum dots 7A each including a core made of CdSe and a shell made of ZnS. The colloidal solution is applied to form the quantum-dot layer 7. In this case, the quantum-dot layer 7 has an ionization potential of 5.2 eV and an electron affinity of 2.9 eV. Hence, the quantum-dot layer 7 has a bandgap of 2.3 eV.

If the quantum dots 7A of the quantum-dot layer 7 have a shell, the values of the electron affinity and the ionization potential of the quantum-dot layer 7 are those of the shell. If the quantum dots 7A of the quantum-dot layer 7 have a core alone, the values of the electron affinity and the ionization potential of the quantum-dot layer 7 are those of the core.

Note that, in this embodiment, an intermediate layer is provided in an interface between the hole-transport layer 6 and the quantum-dot layer 7. The intermediate layer may be formed by the same technique as the hole-transport layer 6 is formed by. The intermediate layer may be capable of reducing the risk that the holes to be injected from the hole-transport layer 6 into the quantum-dot layer 7 are captured by, for example, the dangling bonds or the defects found in the interface between the hole-transport layer 6 and the quantum-dot layer 7.

In this embodiment, the electron-transport layer 8, an n-type semiconductor layer, contains Si as an electron transport material. In this case, the electron-transport layer 8 in this embodiment has an ionization potential of 4.7 eV and an electron affinity of 3.6 eV. Hence, the electron-transport layer 8 has a bandgap of 1.1 eV.

In this embodiment, the electron-transport layer 8 may be formed by application of a colloidal solution. Other than the application of a colloidal solution, the electron-transport layer 8 can be formed by such a technique as vacuum vapor deposition or sputtering. Note that, in this embodiment, an electron-injection layer may be additionally provided in an interface between the electron-transport layer 8 and the second electrode 9.

The barrier layer 10 seals the entire surface of the light-emitting element 2 to keep such substances as water and a foreign matter from reaching the light-emitting element 2. The barrier layer 10 protects the organic materials, found in the structure of the light-emitting element 2, from a cause of oxidization found in the external environment, and ensures long-term reliability of the light-emitting device 1. The barrier layer 10 may be formed of SiN or SiO₂ by, for example, plasma CVD, or of a filling containing an amorphous fluorine composition such as dimethyl silicone or tetrafluoroethylene (TFE). In order to avoid absorption of light, a seal material contained in the barrier layer 10 is preferably high in visible light transmittance, low in dispersion of oxygen and water, and stable to near-ultraviolet light.

The array substrate 3 is driven to apply a voltage between the electrodes of the light-emitting element 2, such that the holes and the electrons are injected respectively from the first electrode 4 and the second electrode 9. As illustrated in FIG. 1(a), the holes from the first electrode 4 reach the quantum-dot layer 7 through the hole-injection layer 5 and the hole-transport layer 6. The electrons from the second electrode 9 reach the quantum-dot layer 7 through the electron-transport layer 8.

A hole injection barrier between the first electrode 4 and the hole-injection layer 5 corresponds to a difference between the work function of the first electrode 4 and the ionization potential of the hole-injection layer 5. Moreover, an electron injection barrier between the second electrode 9 and the electron-transport layer 8 corresponds to a difference between the work function of the second electrode 9 and the electron affinity of the electron-transport layer 8.

Likewise, a hole injection barrier between the hole-transport layer 6 and the quantum-dot layer 7 is a difference in energy corresponding to a difference between the ionization potentials of the hole-transport layer 6 and the quantum-dot layer 7. Furthermore, an electron injection barrier between the electron-transport layer 8 and the quantum-dot layer 7 corresponds to a difference between the electron affinities of the electron-transport layer 8 and the quantum-dot layer 7.

In this embodiment, the quantum-dot layer 7 is greater in ionization potential than the electron-transport layer 8. Moreover, in this embodiment, the quantum-dot layer 7 is greater in bandgap than the electron-transport layer 8.

Hence, this embodiment can relatively reduce both of the differences; that is, the difference between the work function of the second electrode 9 and the electron affinity of the electron-transport layer 8, and the difference between the electron affinities of the electron-transport layer 8 and the quantum-dot layer 7. Such a feature improves efficiency in transportation of the electrons from the second electrode 9 to the quantum-dot layer 7, and increases density of the electrons in the quantum-dot layer 7.

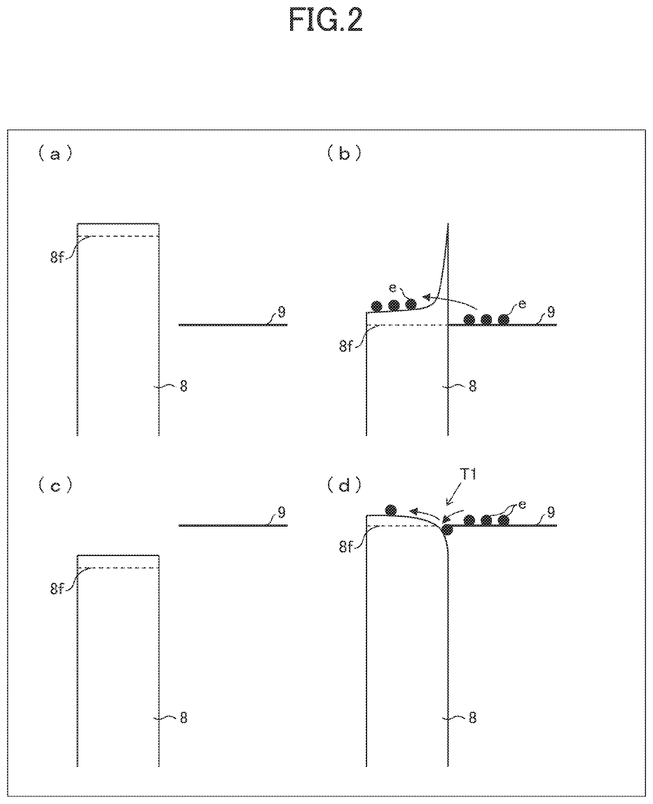

FIG. 2 is an energy band diagram illustrating variation in a LUMO level and a Fermi level of each of the electron-transport layer 8 and the second electrode 9 before and after junction. FIG. 2 illustrates the surroundings of the LUMO level of the electron-transport layer 8 and the Fermi level of the second electrode 9. Note that, as the illustrations of FIG. 2 show, the electron-transport layer 8 has a Fermi level 8f. As to an n-type semiconductor layer, the Fermi level is commonly positioned in the vicinity of the LUMO level.

FIG. 2(a) illustrates a case where the Fermi level 8f is higher than the Fermi level of the second electrode 9. In this case, the electron-transport layer 8 and the second electrode 9 are joined together by Schottky junction, and the energy bands of the electron-transport layer 8 and the second electrode 9 vary as illustrated in FIG. 2(b).

That is, the junction between the electron-transport layer 8 and the second electrode 9 equalizes the Fermi level 8f and the Fermi level of the second electrode 9. Moreover, the LUMO level of the electron-transport layer 8 varies to rise, by the difference between the Fermi level 8f and the Fermi level of the second electrode 9, in the vicinity of the interface between the electron-transport layer 8 and the second electrode 9. Hence, a barrier of the electron-transport layer 8 is formed in the vicinity of the interface between the electron-transport layer 8 and the second electrode 9.

Here, the Fermi level 8f of the electron-transport layer 8 is close to the LUMO level of the electron-transport layer 8. That is, as illustrated in FIG. 2(b), the variation in the LUMO level of the electron-transport layer 8 occurs only in an extremely thin region. Hence, the barrier of the electron-transport layer 8 is formed only in the extremely thin region in the vicinity of the interface between the electron-transport layer 8 and the second electrode 9.

Thus, when a voltage is applied to the light-emitting element 2, electrons e of the second electrode 9 can reach the electron-transport layer 8 through the barrier acting as a tunnel and found in the interface between the electron-transport layer 8 and the second electrode 9.

Meanwhile, FIG. 2(c) illustrates a case where the Fermi level 8f is lower than the Fermi level of the second electrode 9. In this case, the electron-transport layer 8 and the second electrode 9 are joined together, and the energy bands of the electron-transport layer 8 and the second electrode 9 vary as illustrated in FIG. 2(d). That is, the LUMO level of the electron-transport layer 8 varies to fall, by the difference between the Fermi level 8f and the Fermi level of the second electrode 9, in the vicinity of the interface between the electron-transport layer 8 and the second electrode 9.

Hence, as illustrated in FIG. 2(d), a well-type electron trap T1 appears in the interface between the electron-transport layer 8 and the second electrode 9. Thus, the electron trap T1 inhibits the injection of electrons e from the second electrode 9 into the electron-transport layer 8.

As can be seen, in view of reducing contact resistance between the electron-transport layer 8 and the second electrode 9, and of enhancing injection of the electrons from the second electrode 9 into the electron-transport layer 8, in this embodiment, the Fermi level of the electron-transport layer 8 is preferably higher than the Fermi level of the second electrode 9.

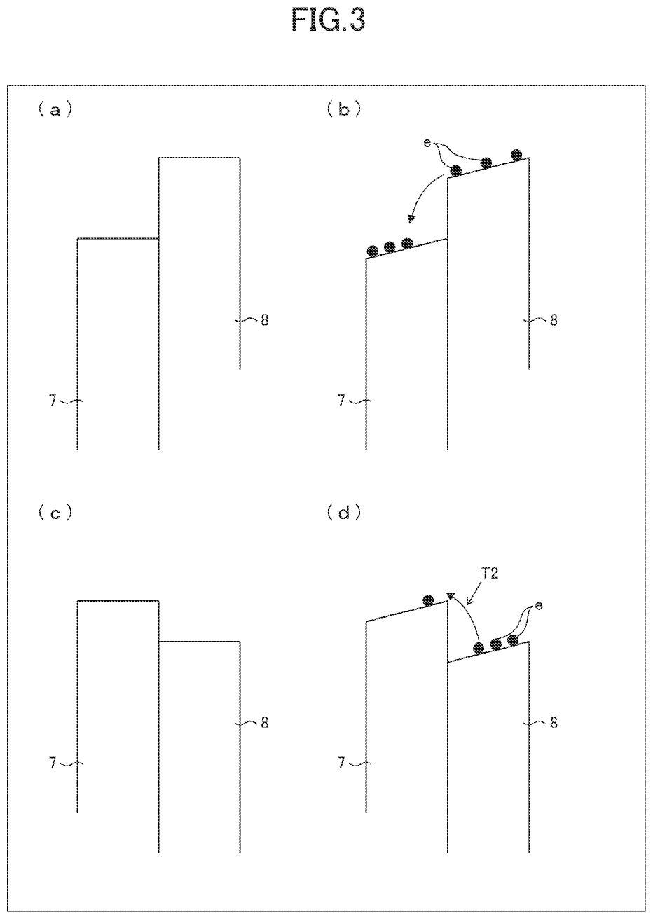

FIG. 3 is an energy band diagram illustrating variation in a LUMO level of each of the quantum-dot layer 7 and the electron-transport layer 8 before and after application of a voltage to the light-emitting element 2. FIG. 3 illustrates the surroundings of the LUMO levels of the quantum-dot layer 7 and the electron-transport layer 8.

FIG. 3(a) illustrates a case where the LUMO level of the electron-transport layer 8 is higher than the LUMO level of the quantum-dot layer 7. Here, a voltage is applied to the light-emitting element 2 to generate an electric field in each of the layers in the light-emitting element 2. Hence, the LUMO level of each of the layers in the light-emitting element 2 varies to rise from toward the first electrode 4 to toward the second electrode 9. Thus, when the voltage is applied to the light-emitting element 2, the LUMO levels of the quantum-dot layer 7 and the electron-transport layer 8 vary as illustrated in FIG. 3(b).

Here, the LUMO level of the electron-transport layer 8 is higher than the LUMO level of the quantum-dot layer 7. Hence, whether or not a voltage is applied to the light-emitting element 2, there is no barrier formed for blocking injection of the electrons from the electron-transport layer 8 into the quantum-dot layer 7, as illustrated in FIG. 3(b).

Meanwhile, FIG. 3(c) illustrates a case where the LUMO level of the electron-transport layer 8 is lower than the LUMO level of the quantum-dot layer 7. In this case, when a voltage is applied to the light-emitting element 2, the LUMO levels of the quantum-dot layer 7 and the electron-transport layer 8 vary as illustrated in FIG. 3(d).

Here, with the voltage applied to the light-emitting element 2, a well-type electron trap T2 appears in the interface between the quantum-dot layer 7 and the electron-transport layer 8 as illustrated in FIG. 3(d). Thus, the electron trap T2 inhibits the injection of the electrons e from the electron-transport layer 8 into the quantum-dot layer 7.

This embodiment shows an example in which the light-emitting element 2 includes: the quantum-dot layer 7 containing the quantum dots 7A each having a core made of CdSe and a shell made of ZnS; the electron-transport layer 8 containing Si as an electron transport material; and the second electrode 9 containing Al. In such a case, the Fermi level 8f of the electron-transport layer 8 is higher than the Fermi level of the second electrode 9, and the LUMO level of the quantum-dot layer 7 is higher than the LUMO level of the electron-transport layer 8.

Here, the electron-transport layer 8 contains Si, making it possible to facilitate production of an n-type semiconductor with high carrier concentration. Thus, the Fermi level 8f of the electron-transport layer 8 can be easily raised. Thanks to the above reasons, the light-emitting element 2 according to this embodiment significantly achieves an advantageous effect of reducing contact resistance between the electron-transport layer 8 and the second electrode 9.

Moreover, as described above, the reduction in the contact resistance between the electron-transport layer 8 and the second electrode 9 brings improvement in efficiency of injecting the electrons from the second electrode 9 to the electron-transport layer 8. The improvement in the electron injection acts more significantly than inhibition of injecting the electrons from the electron-transport layer 8 into the quantum-dot layer 7. Hence, with Si contained in the electron-transport layer 8, the light-emitting element 2 according to this embodiment achieves efficient transportation of the electrons from the second electrode 9 to the quantum-dot layer 7. Moreover, Si is relatively easily produced industrially in large amount. Thus, the electron-transport layer 8, which includes Si, contributes to reduction in production cost of the light-emitting element 2.

In this embodiment, the electron-transport layer 8 includes, but not limited to, Si. In particular, the electron-transport layer 8 may contain any given material as long as the electron-transport layer 8 is lower in ionization potential and bandgap than the quantum-dot layer 7.

For example, the electron-transport layer 8 may include an inorganic semiconductor. Such a feature makes it possible to easily improve mobility and carrier concentration of the electrons, and to reduce contact resistance between the electron-transport layer 8 and the second electrode 9.

Moreover, for example, the electron-transport layer 8 may include a metal oxide. Such a feature can enhance light transmittance of the electron-transport layer 8. Hence, if the light-emitting device 1 is of a top-emission type to emit light from toward the second electrode 9, the above feature allows the light-emitting device 1 to emit light more efficiently.

Furthermore, for example, the electron-transport layer 8 may include a conductive organic substance. Such a feature makes it possible to reduce concentration of a hydroxyl group appearing in the interface between the quantum-dot layer 7 and the electron-transport layer 8, and to reduce a trap of the electrons in the interface between the quantum-dot layer 7 and the electron-transport layer 8. In addition, the electron-transport layer 8 including a conductive organic substance can be easily deposited by application, contributing to simplification of steps for forming the electron-transport layer 8.

In this embodiment, the hole-transport layer 6 is smaller in electron affinity than the quantum-dot layer 7. Such a feature inhibits injection of the electrons from the quantum-dot 7 into the hole-transport layer 6. Hence, the hole-transport layer 6 can reduce the electrons, injected into the quantum-dot layer 7, flowing out toward the first electrode 4.

### Second Embodiment

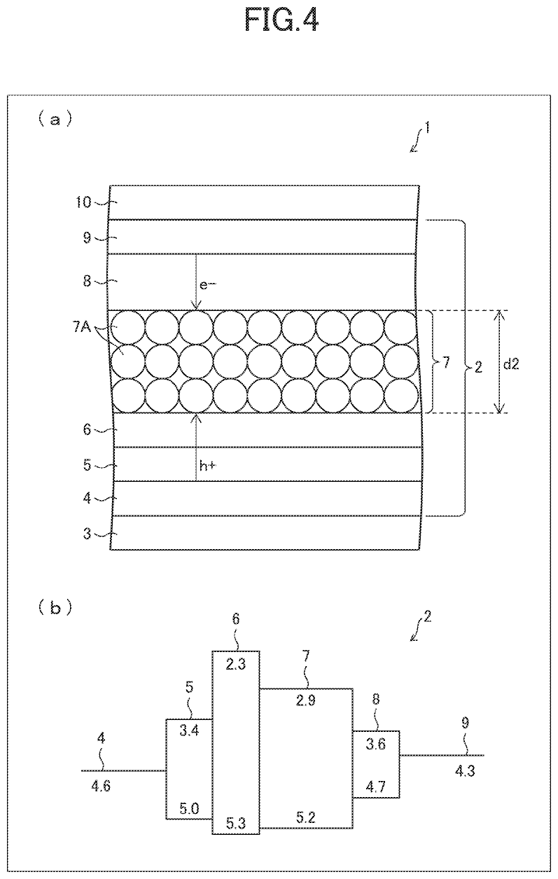

FIG. 4(a) is a schematic cross-sectional view of the light-emitting device 1 according to a second embodiment. As illustrated in FIG. 4(a), the light-emitting device 1 according to this embodiment may be the same in configuration as the light-emitting device 1 according to the previous embodiment, except that the former is different in film thickness of the quantum-dot layer 7 from the latter. Hence, the energy bands of the layers in the light-emitting element 2 according to this embodiment may have the same relationship as those of the layers in the light-emitting element 2 according to the previous embodiment as illustrated in FIG. 4(b).

In this embodiment, the quantum-dot layer 7 has a film thickness d2. The film thickness d2 is greater than the film thickness d1. In particular, the film thickness d2 is greater than a film thickness of the electron-transport layer 8. The film thickness of the quantum-dot layer 7 can be designed by controlling the number of the layers of the quantum dots 7A. Specifically, the film thickness d2 is 50 nm or greater and 250 nm or smaller.

Described below with reference to FIG. 5 are advantageous effects of the light-emitting device 1 according to this embodiment. FIG. 5(a) is an excerpt of energy bands of the quantum-dot layer 7 and the electron-transport layer 8 from among the layers of the light-emitting element 2 according to the previous embodiment. FIG. 5(b) is an excerpt of energy bands of the quantum-dot layer 7 and the electron-transport layer 8 from among the layers of the light-emitting element 2 according to this embodiment.

In the drawings of FIG. 5, a reference sign HD denotes distribution of the holes injected into the quantum-dot layer 7. A reference sign ED denotes distribution of the electrons injected into the quantum-dot layer 7. That is, the area of the hole distribution HD indicates a total number of the holes injected from toward the first electrode 4. The area of the electron distribution ED indicates a total number of the electrons injected from toward the second electrode 9.

As illustrated in FIG. 5, the total number of the electrons injected into the quantum-dot 7 is larger than the total number of the holes injected into the quantum-dot 7. That is, in the quantum-dot layer 7, the electrons injected into the quantum-dot layer 7 is higher in carrier concentration than the holes injected into the quantum-dot layer 7. This is because efficiency in injecting the electrons from the second electrode 9 into the quantum-dot layer 7 through the electron-transport layer 8 is higher than efficiency in injecting the holes from the first electrode 4 into the quantum-dot layer 7 through the hole-injection layer 5 and the hole-transport layer 6 in the above embodiments. Hence, in the above embodiments, the electrons are excessively found in the quantum-dot layer 7.

The electrons in the quantum-dot layer 7 are transported by drift of the electric field generated in the quantum-dot layer 7. Since mobility of the carriers by the drift is relatively high, mobility of the electrons is relatively high. Hence, as the electron distribution ED in FIG. 5 clearly shows, the electrons injected into the quantum-dot layer 7 are deemed to be substantially uniformly found between toward the second electrode 9 and the first electrode 4, regardless of the position of the quantum-dot layer 7.

Meanwhile, the holes in the quantum-dot layer 7 are transported by hopping conduction between bonding orbitals of organic molecules such as a ligand of the quantum dots 7A. In the hopping conduction, the holes are significantly low in mobility; that is, the mobility is 0.02 cm²/V·sec or higher and 20 cm²/V·sec or lower. Hence, as the hole distribution HD in FIG. 5 clearly shows, the holes injected into the quantum-dot layer 7 are localized in the quantum-dot layer 7 toward the first electrode 4.

Here, as illustrated in FIG. 5(a), if the quantum-dot layer 7 is relatively small in film thickness as seen in the light-emitting element 2 according to the previous embodiment, the hole distribution HD has a foot reaching an end, of the quantum-dot layer 7, toward the second electrode 9. That is, in the light-emitting element 2 according to the previous embodiment, the holes injected into the quantum-dot layer 7 reach the interface between the quantum-dot layer 7 and the electron-transport layer 8.

In the above embodiments, the quantum-dot layer 7 is greater in ionization potential than the electron-transport layer 8. Thus, the barrier to the transportation of the holes from the quantum-dot layer 7 to the hole-transport layer 8 is extremely small. Hence, if the holes are found in the interface between the quantum-dot layer 7 and the electron-transport layer 8, the holes might flow out of the quantum-dot layer 7 to the electron-transport layer 8 as indicated by the arrow in FIG. 5(a). Consequently, in the light-emitting element 2 according to the previous embodiment, the flow of the holes out of the quantum-dot layer 7 to the electron-transport layer 8 could further increase the number of the excessive electrons found in the quantum-dot layer 7.

Meanwhile, as illustrated in FIG. 5(b), if the quantum-dot layer 7 is relatively great in film thickness as seen in the light-emitting element 2 according to this embodiment, the hole distribution HD has a foot reaching substantially a center of the quantum-dot layer 7, and the foot does not reach the end, of the quantum-dot layer 7, toward the second electrode 9. That is, in the light-emitting element 2 according to this embodiment, the holes injected into the quantum-dot layer 7 do not reach the interface between the quantum-dot layer 7 and the electron-transport layer 8.

Consequently, in the light-emitting element 2 according to this embodiment, the flow of the holes out of the quantum-dot layer 7 to the electron-transport layer 8 decreases, regardless of the height of the barrier to the transport of the holes from the quantum-dot layer 7 to the electron-transport layer 8. Hence, the light-emitting element 2 according to this embodiment can reduce the number of excessive electrons found in the quantum-dot layer 7.

In this embodiment, the holes and the electrons in the quantum-dot layer 7 recombine only in a region, of the quantum-dot layer 7, in which the hole distribution HD is found. That is, in the light-emitting element 2 according to this embodiment, the holes and the electrons in the quantum-dot layer 7 recombine only in a recombination region 11 formed, in the quantum-dot layer 7, toward the first electrode 4 as illustrated in FIG. 5(b).

In this embodiment, as described above, the electrons in the quantum-dot layer 7 are distributed substantially uniformly. Here, it is only in the recombine region 11 of the quantum-dot layer 7 that the holes and the electrons recombine in the quantum-dot layer 7. Of the electrons in the quantum-dot layer 7, a total number of electrons contributing to the recombination is smaller than the total number of the electrons in the quantum-dot layer 7.

Meanwhile, the holes in the quantum-dot layer 7 are localized in the recombination region 11. Hence, a total number of holes contributing to the recombination is approximately the same as the total number of the holes in the quantum-dot layer 7.

Hence, in the quantum-dot layer 7, even if electrons are larger in total number than holes, such a feature reduces a difference between the total numbers of the electrons and the holes contributing to the recombination. Thus, the feature can further reduce the number of excessive electrons found in the quantum-dot layer 7. When the number of excessive electrons is reduced in the quantum-dot layer 7, a deactivation process due to, for example, the Auger recombination occurs less frequently, improving light-emission efficiency.

In this embodiment, the holes injected into the quantum-dot layer 7 may have a mobility of lower than, or equal to, a quarter of a mobility of the electrons injected into the quantum-dot layer 7. Such a feature more clearly exhibits uniform distribution of the electrons and localization of the holes in the quantum-dot layer 7, making it possible to further reduce the number of excessive electrons.

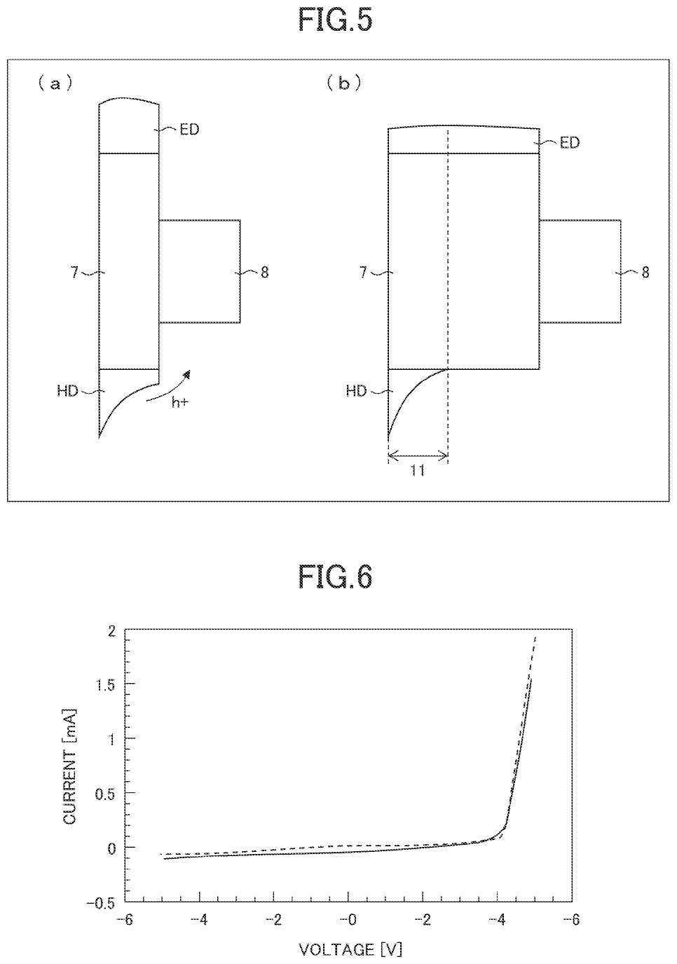

Here, the region in which the holes are localized in the quantum-dot layer 7; that is, the thickness of the recombination region 11, is studied in view of voltage-current characteristics of the light-emitting element 2 according to this embodiment. In the graph of FIG. 6, the solid line indicates a measurement result of voltage-current characteristics of the light-emitting element 2 according to this embodiment.

As can be clearly seen in FIG. 6, the light-emitting element 2 according to this embodiment has a characteristic; that is, when a voltage over a certain threshold is applied to the light-emitting element 2, current density of the light-emitting element 2 suddenly increases. Such a characteristic shows that, in the multilayer structure of the light-emitting element 2 according to this embodiment, a p-n junction or a p-i-n junction similar to an inorganic light-emitting diode is formed. That is, the voltage-current characteristic of the light-emitting element 2 according to this embodiment exhibits a rectification characteristic based on the p-n junction or the p-i-n junction.

Here, as to the multilayer structure of the light-emitting element 2 according to this embodiment, the hole-injection layer 5 and the hole-transport layer 6 are of the p-type, the quantum-dot layer 7 is of the i-type, and the electron-transport layer 8 is of the n-type. Commonly, between layers having a p-n junction or a p-i-n junction, a relational expression of a voltage-current density characteristic is represented by the Shockley diode equation (1) below:

J=J₀{exp(qV/nkT)−1} (1)

where J is the current density, V is the applied voltage, Jₒ is the reverse saturation current, q is the charge of an electron, k is the Boltzmann constant, and T is the junction temperature. Moreover, n is a constant referred to as a diode constant, reflecting behavior of carriers between the layers joined together.

In an ideal inorganic diode, for example, injected carriers diffuse into the junction structure and reach a conductive layer on an opposing side. Hence, the constant n is 1. As to a Si diode, the constant n is known to actually range from 0.9 to 1. Furthermore, in the ideal inorganic light-emitting diode, the recombination of the electrons and the holes in the junction structure is deemed to occur in the midpoint of the junction width on average. Hence, the constant n is 2. If the carriers injected into a layer are transported in the layer by diffusion alone, as seen in an inorganic electronic device, an ideal constant n is 1. If diffusion and recombination are observed as seen in an inorganic light-emitting device, the constant n is determined depending on a position of the recombination. In such a case, the light-emitting recombination occurs most ideally in a center of the light-emission layer (equivalent to the total width of the p-n junction). Hence, an ideal constant n is 2.

In other words, in the case of the light-emitting recombination, the electrons and the holes injected into the junction structure can be deemed to diffuse in a distance as far as a half of the junction width and to recombine together. Here, as described above, it is most suitable for both the electrons and the holes to be found in the center of the light-emission layer at the same concentration. The constant n is 2. If the distribution of the holes or the electrons are off the center, the constant n is determined by carriers diffusing in a short distance. For example, if the holes can diffuse in a distance of no farther than one-third of the total width of the light-emission layer from the interface between the hole-transport layer and the light-emission layer, the constant n is 3. Conversely, even if the electrons can diffuse no farther than one-third of the total width of the light-emission layer from the interface between the electron-transport layer and the light-emission layer, the constant n is also 3.

An example of a current-injection light-emitting element capable of achieving high light-emission efficiency includes a GaInN-based inorganic light-emitting diode. Commonly, the GaInN-based inorganic light-emitting diode has a diode constant of approximately up to 3. The reason why the constant n is greater than 2 is that, the light-emission layer of the GaInN-based inorganic light-emitting diode has a center of non-light emission such as lattice defect or agglomeration of In. The center of non-light emission inhibits dispersion of the electrons and the holes. Hence, in the light-emission layer of the GaInN-based inorganic light-emitting diode, recombination of the electrons and the holes is observed in a region an average of one-third of the film thickness of the light-emission layer. As can be seen, it is difficult to achieve the ideal diode constant n=2 even in the GaInN-based inorganic light-emitting diode. The diode constant under the current circumstances remains approximately n=3. Hence, even in a light-emitting element including a light-emission layer containing quantum dots, the constant n available under the current circumstances is deemed approximately 3.

Moreover, as described above, the mobility of the electrons is commonly higher than the mobility of the holes, and the holes are localized toward the light-emission layer in relation to the interface of the p-type layer. Hence, in the light-emission layer of the GaInN-based inorganic light-emitting diode, recombination of the electrons and the holes is observed in a region approximately one-third of the film thickness of the light-emission layer from the interface of the p-type layer.

Taking the above characteristics of the p-i-n junction into consideration, FIG. 6 shows by a broken line a result of a curve-fitting of actually measured values, using the equation (1). In the curve-fitting, V is the voltage applied to the light-emitting element 2, and T is the temperature at the measurement. J₀ is the actually measured value obtained when a reverse voltage is applied to the light-emitting element 2.

The result shows that the equation (1) can reproduce the actually measured values indicated in FIG. 6 when the constant n is 17. Hence, as can be understood from the above arguments, the light-emitting element 2 according to this embodiment includes the recombination region 11; that is, a region approximately one-seventeenth of the film thickness of the quantum-dot layer 7 from the interface between the hole-transport layer 6 and the quantum-dot layer 7.

The multilayer structure of the inorganic light-emitting diode is formed of single crystals. Even though the diffusion length for which the electrons and the holes diffuse in the light-emission layer is affected by lattice defect, the above condition is the best one for an available light-emitting element. Meanwhile, the diffusion length of the electrons and the holes in a QLED formed of different materials sequentially multilayered has difficulty in exceeding the diffusion length of the electrons and the holes in the inorganic light-emitting diode at best, because of effects of grain boundaries, or defects, of the layers. Hence, when, in this embodiment, the actually measured values of the voltage-current characteristics of the light-emitting element 2 are curve-fitted using the equation (1), the value n, namely the diode constant, is 3 or greater, which is the same as the diode constant of the GaInN-based inorganic light-emitting diode capable of achieving high light-emission efficiency. Thanks to such a feature, the holes injected into the quantum-dot layer 7 are localized in a position one-third or less of the total width of the light-emission layer from the interface between the hole-transport layer and the light-emission layer. Hence, the feature makes it possible to more efficiently reduce the number of excessive electrons in the quantum-dot layer 7. Moreover, as can be seen, the equation (1) can reproduce the actually measured values indicated in FIG. 6 when the diode constant n is 17. Hence, the diode constant n is preferably 3 or greater and 17 or smaller.

If, in this embodiment, the actually measured values of the voltage-current characteristics of the light-emitting element 2 are curve-fitted using the equation (1), the value n, namely the diode constant, is preferably 3 or greater, which is the same as the diode constant of the GaInN-based inorganic light-emitting diode capable of achieving high light-emission efficiency. Thanks to such a feature, the holes injected into the quantum-dot layer 7 are more clearly localized, making it possible to more efficiently reduce the number of excessive electrons in the quantum-dot layer 7.

Studied next is a relationship between a film thickness of the quantum-dot layer 7 in the light-emitting element 2 according to the embodiments and the characteristics of the light-emitting element 2.

First, prepared as the light-emitting elements 2 according to the embodiments were light-emitting elements 2 according to Examples 1 to 5. The light-emitting elements 2 had a film thickness ranging from 50 to 270 nm. Next, the characteristics of each of the light-emitting elements 2 were actually measured. Table 1 below shows measurement results of the characteristics of the light-emitting elements 2.

TABLE 1

| Characteristic | | | | | | |
|---|---|---|---|---|---|---|
| Parameter | Unit | Example 1 | Example 2 | Example 3 | Example 4 | Example 5 |
| QD Film | nm | 30 | 50 | 150 | 250 | 270 |
| Thickness | | | | | | |
| Vₜₕ | V | 3.6 | 3.4 | 3.4 | 3.4 | 3.4 |
| Vᵢ | V | 3.7 | 3.5 | 3.5 | 3.5 | 3.5 |
| Lₘₐₓ | cd/m² | 38000 | 56000 | 57000 | 57600 | 54000 |
| Jₘₐₓ | mA/cm² | 590 | 500 | 495 | 500 | 560 |
| EQEₘₐₓ | % | 8 | 12 | 12.1 | 12.3 | 10.3 |

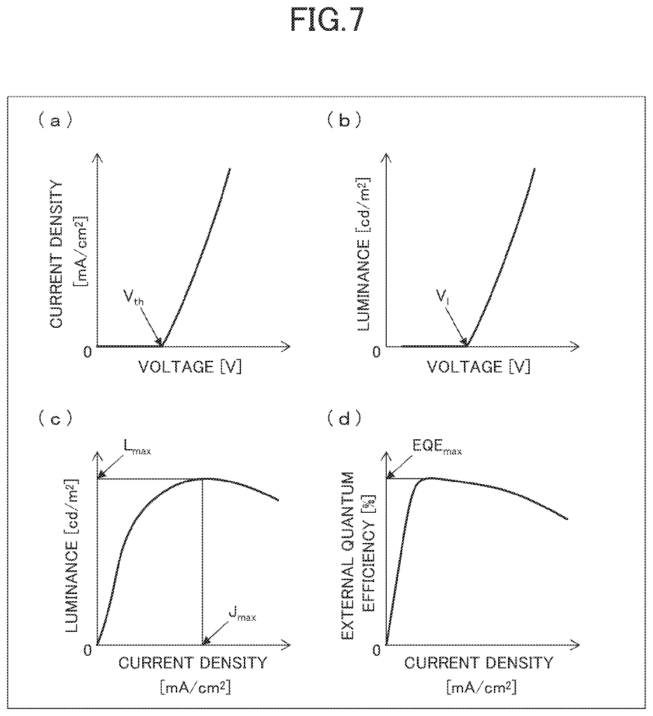

Note that, in Table 1, the row “QD Film Thickness” indicates a film thickness of the quantum-dot layer 7 in each of the light-emitting elements 2. The row “Vₜₕ” indicates a level of a threshold voltage observed when the current density of the light-emitting element 2 suddenly starts to increase while a voltage to be applied to the light-emitting element 2 is gradually increased, as illustrated in FIG. 7(a). The row “Vᵢ” indicates a level of a threshold voltage observed when the luminance of light emitted from the light-emitting element 2 suddenly starts to increase while a voltage to be applied to the light-emitting element 2 is gradually increased, as illustrated in FIG. 7(b). The row “Lₘₐₓ” indicates a level of a maximum luminance of light emitted from the light-emitting element 2 while the density of a current applied to the light-emitting element 2 is gradually increased, as illustrated in FIG. 7(c). The row “Jₘₐₓ” indicates a level of a current density in the light-emitting element 2 observed when the light emitted from the light-emitting element 2 is at maximum luminance, as illustrated in FIG. 7(c). The row “EQEₘₐₓ” indicates a level of maximum external quantum efficiency that the light-emitting element 2 reaches while the density of a current applied to the light-emitting element 2 is gradually increased, as illustrated in FIG. 7(d).

As shown in Table 1, the light-emitting element 2 according to Example 1, whose quantum-dot layer 7 has a film thickness of 30 nm, exhibits an external quantum efficiency of as low as 8 percent. Moreover, the light-emitting element 2 according to Example 5, whose quantum-dot layer 7 has a film thickness of 270 nm, exhibits an external quantum efficiency of as low as 10.3 percent. Meanwhile, any of the light-emitting elements 2 according to Examples 2 to 4, whose quantum-dot layer 7 has a film thickness of 50 nm or greater and 250 nm or smaller, exhibit an external quantum efficiency reaching 12 percent or greater.

An improvement is observed of the external quantum efficiencies of the light-emitting elements 2 whose quantum-dot layer 7 has a film thickness of 50 nm or greater. This is because the reductions in the amounts of the holes flowing out of the quantum-dot layer 7 and of excessive electrons in the recombination region 11 improve efficiency in emission of light from the light-emitting element 2. Moreover, an improvement is observed of the external quantum efficiencies of the light-emitting elements 2 whose quantum-dot layer 7 has a film thickness of 250 nm or less. This is because a reduction is observed of an increase in the entire resistance of the light-emitting elements 2 in association with an increase in the film thickness of the quantum-dot layers 7.

As can be seen, the film thickness of the quantum-dot layer 7 in the light-emitting element 2 according to this embodiment is preferably 50 nm or greater and 250 nm or smaller.

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined to achieve a new technical feature.

1. A light-emitting element, comprising:
an anode; a cathode; a quantum-dot layer provided between the anode and the cathode, and containing quantum dots; and an electron-transport layer provided between the cathode and the quantum-dot layer, and placed in contact with the quantum-dot layer,
in an interface between the quantum-dot layer and the electron-transport layer, the quantum-dot layer being greater in ionization potential than the electron-transport layer, and the quantum-dot layer being greater in bandgap than the electron-transport layer, wherein
the quantum-dot layer has a film thickness of 50 nm or greater and 250 nm or smaller.

2. (canceled)

3. The light-emitting element according to claim 1, wherein
the quantum-dot layer is greater in film thickness than the electron-transport layer.

4. The light-emitting element according to claim 1, wherein
holes injected into the quantum dot layer have a mobility of 0.02 cm²/V·sec or higher and 20 cm²/V·sec or lower.

5. The light-emitting element according to claim 1, wherein
holes injected into the quantum-dot layer have a mobility of lower than, or equal to, a quarter of a mobility of electrons injected into the quantum-dot layer.

6. The light-emitting element according to claim 1, wherein
a voltage-current characteristic of the light-emitting element exhibits a rectification characteristic based on a p-n junction or a p-i-n junction.

7. The light-emitting element according to claim 6, wherein
when the voltage-current characteristic is curve-fitted using a Shockley diode equation based on the p-n junction, a diode constant of the voltage-current characteristic is 3 or greater.

8. The light-emitting element according to claim 4, wherein
electrons injected into the quantum-dot layer is higher in carrier concentration than the holes injected into the quantum-dot layer.

9. The light-emitting element according to claim 1, wherein
the cathode and the electron-transport layer are joined together by Schottky junction.

10. The light-emitting element according to claim 1, wherein
the electron-transport layer is an inorganic semiconductor.

11. The light-emitting element according to claim 1, wherein
the electron-transport layer is a metal oxide.

12. The light-emitting element according to claim 1, wherein
the electron-transport layer is a conductive organic substance.

13. The light-emitting element according to claim 1, further comprising
a hole-transport layer provided between the anode and the quantum-dot layer.

14. The light-emitting element according to claim 13, wherein
the hole-transport layer is smaller in electron affinity than the quantum-dot layer.

15. A light-emitting device, comprising the light-emitting element according to claim 1.

16. A light-emitting element, comprising:
an anode; a cathode; a quantum-dot layer provided between the anode and the cathode, and containing quantum dots; and an electron-transport layer provided between the cathode and the quantum-dot layer, and placed in contact with the quantum-dot layer,
in an interface between the quantum-dot layer and the electron-transport layer, the quantum-dot layer being greater in ionization potential than the electron-transport layer, and the quantum-dot layer being greater in bandgap than the electron-transport layer, wherein
the quantum-dot layer is greater in film thickness than the electron-transport layer.

17. A light-emitting device, comprising the light-emitting element according to claim 16.

18. A light-emitting element, comprising:
an anode; a cathode; a quantum-dot layer provided between the anode and the cathode, and containing quantum dots; and an electron-transport layer provided between the cathode and the quantum-dot layer, and placed in contact with the quantum-dot layer,
in an interface between the quantum-dot layer and the electron-transport layer, the quantum-dot layer being greater in ionization potential than the electron-transport layer, and the quantum-dot layer being greater in bandgap than the electron-transport layer,
wherein a voltage-current characteristic of the light-emitting element exhibits a rectification characteristic based on a p-n junction or a p-i-n junction, and
when the voltage-current characteristic is curve-fitted using a Shockley diode equation based on the p-n junction, a diode constant of the voltage-current characteristic is 3 or greater.

19. A light-emitting device, comprising the light-emitting element according to claim 18.
